(19) United States
(12) Patent Application Publication
(10) Pub. No.: US 2020/0303248 A1
(43) Pub. Date: Sep. 24, 2020

(54) CIRCUIT WAFER AND METHOD FOR MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Mamoru Chiba, Fujisawa Kanagawa (JP)

(21) Appl. No.: 16/567,641

(22) Filed: Sep. 11, 2019

(30) Foreign Application Priority Data
Mar. 19, 2019 (JP) 2019-051074

(51) Int. Cl. H01L 21/768; H01L 21/78; H01L 21/283

(52) U.S. Cl. CPC H01L 21/76843; H01L 21/283; H01L 21/78

(57) ABSTRACT

A method for manufacturing a semiconductor device includes forming a first interconnect on a first portion disposed in a chip portion of a semiconductor wafer and forming a second interconnect on a second portion disposed in a dicing portion of the semiconductor wafer. The method includes forming an insulating film covering the first interconnect and the second interconnect. The method includes forming a seed layer on the insulating film. The seed layer is connected to the first interconnect and the second interconnect. The method includes forming a metal plate on a portion of the seed layer disposed in the chip portion. The metal plate is thicker than the seed layer. The method includes singulating the chip portion by removing the dicing portion.

### CROSS-REFERENCE TO RELATED APPLICATIONS

This application is based upon and claims the benefit of priority from Japanese Patent Application No. 2019-051074, filed on Mar. 19, 2019; the entire contents of which are incorporated herein by reference.

### FIELD

Embodiments relate to a circuit wafer and a method for manufacturing a semiconductor device.

### BACKGROUND

Conventionally, a semiconductor device is manufactured by making a circuit wafer by forming a circuit on a semiconductor wafer, and by singulating the circuit wafer by dicing. In such a case, the final quality of the circuit wafer may be evaluated by forming an element for testing in the dicing portion which is removed in the dicing and by evaluating the electrical characteristics of the element. In such a case, the element for testing also is diced when dicing the circuit wafer.

### BRIEF DESCRIPTION OF THE DRAWINGS

FIG. 1A to 1C are cross-sectional views illustrating a method for manufacturing a semiconductor device according to a first embodiment;

FIGS. 2A to 2C are cross-sectional views illustrating the method for manufacturing the semiconductor device according to the first embodiment;

FIGS. 3A to 3C are cross-sectional views illustrating the method for manufacturing the semiconductor device according to the first embodiment;

FIGS. 4A to 4C are cross-sectional views illustrating the method for manufacturing the semiconductor device according to the first embodiment;

FIGS. 5A and 5B are cross-sectional views illustrating the method for manufacturing the semiconductor device according to the first embodiment;

FIG. 6 is a plan view illustrating the method for manufacturing the semiconductor device according to the first embodiment;

FIGS. 7A and 7B are cross-sectional views illustrating the method for manufacturing the semiconductor device according to the first embodiment of the invention;

FIGS. 8A to 8C are cross-sectional views illustrating a method for manufacturing the semiconductor device according to a second embodiment; and

FIGS. 9A and 9B are cross-sectional views illustrating the method for manufacturing the semiconductor device according to the second embodiment.

### DETAILED DESCRIPTION

In general, according to one embodiment, a method is disclosed for manufacturing a semiconductor device. The method includes forming a first interconnect on a first portion disposed in a chip portion of a semiconductor wafer and forming a second interconnect on a second portion disposed in a dicing portion of the semiconductor wafer. The method includes forming an insulating film covering the first interconnect and the second interconnect. The method includes forming a seed layer on the insulating film. The seed layer is connected to the first interconnect and the second interconnect. The method includes forming a metal plate on a portion of the seed layer disposed in the chip portion. The metal plate is thicker than the seed layer. The method includes singulating the chip portion by removing the dicing portion.

In general, according to one embodiment, a circuit wafer includes a semiconductor wafer, a first interconnect, a second interconnect, an insulating film, a first seed layer, a second seed layer, and a metal plate. The first interconnect is provided on the semiconductor wafer in a chip portion. The second interconnect is provided on the semiconductor wafer in a dicing portion. The insulating film is covering the first interconnect and the second interconnect. The first seed layer is connected to the first interconnect and is provided on the insulating film in the chip portion. The second seed layer is connected to the second interconnect and is provided on the insulating film in the dicing portion. The metal plate is provided on the first seed layer and is thicker than the first seed layer.

### First Embodiment

A method for manufacturing a semiconductor device according to a first embodiment will now be described. A circuit wafer is made as an intermediate structure body in the manufacturing processes of the semiconductor device. In the specification, a “semiconductor wafer” refers to a wafer in the state before a circuit pattern is formed. On the other hand, a “circuit wafer” refers to a wafer in the state in which the circuit pattern is formed on the semiconductor wafer by forming interconnect layers, insulating layers, etc.

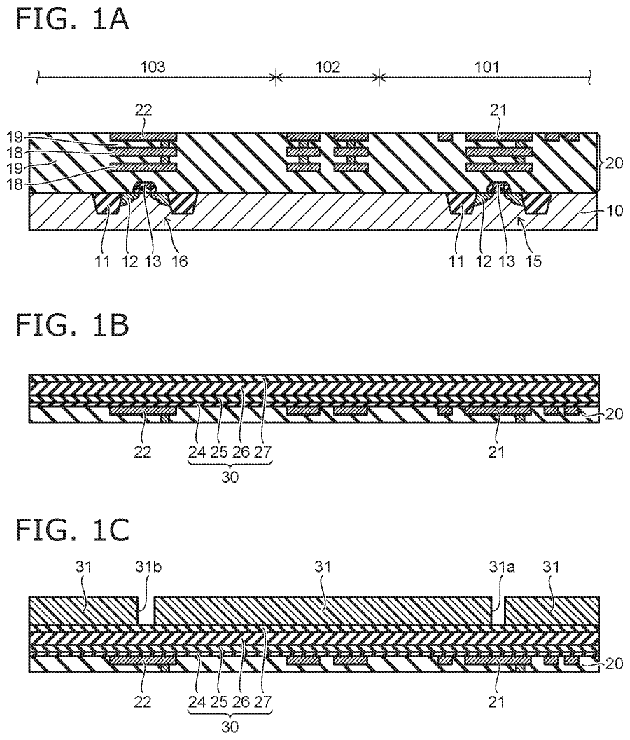

FIGS. 1A to 1C, FIGS. 2A to 2C, FIGS. 3A to 3C, FIGS. 4A to 4C, and FIGS. 5A and 5B are cross-sectional views showing the method for manufacturing the semiconductor device according to the embodiment.

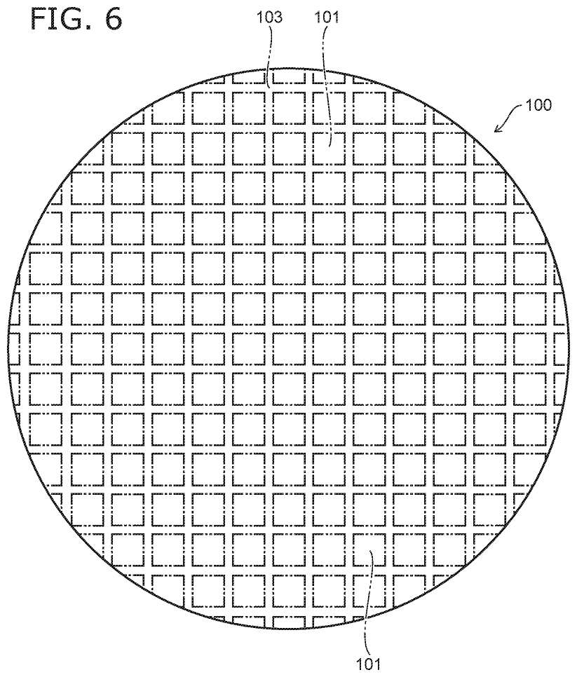

FIG. 6 is a plan view showing the method for manufacturing the semiconductor device according to the embodiment.

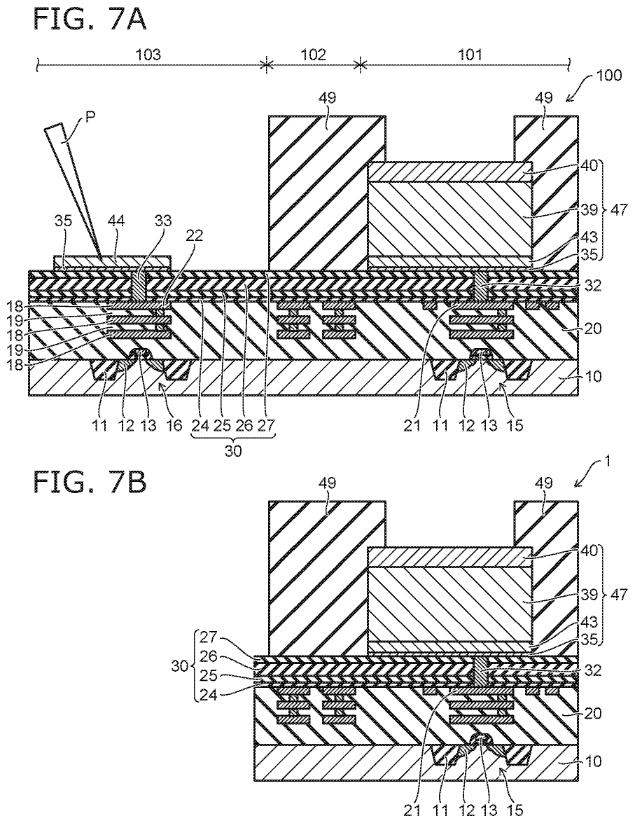

FIGS. 7A and 7B are cross-sectional views showing the method for manufacturing the semiconductor device according to the embodiment.

The drawings are schematic and are abbreviated or enhanced as appropriate. This is similar for the other drawings described below as well.

The method for manufacturing the semiconductor device according to the embodiment will now be described.

First, a semiconductor wafer 10 is prepared as shown in FIG. 1A. The semiconductor wafer 10 is, for example, a wafer made of a single crystal of silicon (Si). A chip portion 101 that becomes the semiconductor device after dicing, a chip ring portion 102 that surrounds the chip portion 101, and a dicing portion 103 that is removed when dicing are set in the semiconductor wafer 10. The configuration of the chip portion 101 is, for example, a rectangle; the configuration of the chip ring portion 102 is, for example, a frame-like configuration; and the configuration of the dicing portion 103 is, for example, a lattice configuration.

Then, STI (Shallow Trench Isolation; an element-separating insulating film) 11, a diffusion layer 12, etc., are formed in the semiconductor wafer 10. Also, a gate electrode 13, etc., are formed on the semiconductor wafer 10. Thus, an element 15 is formed in the portion of the semiconductor wafer 10 disposed in the chip portion 101; and an element 16 is formed in the portion of the semiconductor wafer 10 disposed in the dicing portion 103. The element 15 is an element included in the circuit of the semiconductor device after completion. The element 16 is an element for testing for evaluating the final quality of the circuit wafer and is removed in the dicing process described below. Although MOSFETs (Metal-Oxide-Semiconductor Field-Effect Transistors) are assumed as the elements 15 and 16 in FIG. 1A, the element 15 and the element 16 are not limited to MOSFETs.

Continuing, an interconnect layer 18 and an insulating layer 19 are formed alternately on the semiconductor wafer 10. A multilayer interconnect layer 20 is formed thereby. A portion of the interconnect of the uppermost layer of the multilayer interconnect layer 20 formed in the chip portion 101 is taken as an interconnect 21; and a portion of the interconnect of the uppermost layer of the multilayer interconnect layer 20 formed in the dicing portion 103 is taken as an interconnect 22. For example, the interconnects 21 and 22 are formed of copper (Cu). The interconnect 21 is disposed on the element 15 and is connected to the element 15. The interconnect 22 is disposed on the element 16 and is connected to the element 16.

Then, as shown in FIG. 1B, for example, a silicon nitride layer 24, a silicon oxide layer 25, a silicon nitride layer 26, and a silicon oxide layer 27 are formed in this order. For example, the silicon oxide layers 25 and 27 are formed by CVD (Chemical Vapor Deposition) using TEOS (Tetraethyl orthosilicate (Si(OC₂H₅)₄)) as a source material. Thus, an insulating film 30 in which the silicon nitride layer 24, the silicon oxide layer 25, the silicon nitride layer 26, and the silicon oxide layer 27 are stacked in this order is formed on the multilayer interconnect layer 20. The insulating film 30 covers the interconnects 21 and 22. The semiconductor wafer 10 and the lower portion of the multilayer interconnect layer 20 are not illustrated in FIG. 1B to FIG. 5A.

Continuing as shown in FIG. 1C, a resist pattern 31 is formed on the insulating film 30. In the resist pattern 31, an opening 31a is formed in a portion of the region directly above the interconnect 21; and an opening 31b is formed in a portion of the region directly above the interconnect 22. For example, the resist pattern 31 is formed by forming a continuous resist film by coating a resist material, subsequently exposing by lithography, and by patterning by developing. This is similar for the other resist patterns described below as well.

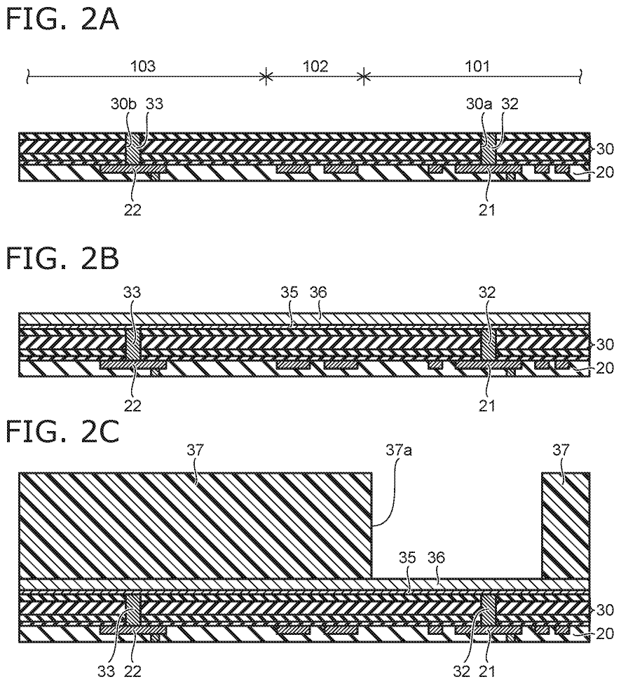

Then, as shown in FIG. 2A, etching such as RIE (Reactive Ion Etching) or the like of the insulating film 30 is performed using the resist pattern 31 as a mask. Thereby, a through-hole 30a that reaches the interconnect 21 is formed in the region of the insulating film 30 directly under the opening 31a; and a through-hole 30b that reaches the interconnect 22 is formed in the region of the insulating film 30 directly under the opening 31b. Subsequently, the resist pattern 31 is removed. Then, a metal, e.g., tungsten (W) is filled into the through-holes 30a and 30b. Thereby, a plug 32 that is connected to the interconnect 21 is formed inside the through-hole 30a; and a plug 33 that is connected to the interconnect 22 is formed inside the through-hole 30b.

Continuing as shown in FIG. 2B, a barrier metal layer 35 is formed on the insulating film 30. For example, the barrier metal layer 35 is formed by depositing titanium (Ti) by electroless plating. Then, for example, a seed layer 36 that includes copper is formed by causing a chemical liquid including copper to contact the barrier metal layer 35. The thickness of the seed layer 36 is, for example, about 0.5 μm. The seed layer 36 is connected to the interconnects 21 and 22 via the barrier metal layer 35 and the plugs 32 and 33.

Then, as shown in FIG. 2C, a resist pattern 37 is formed on the seed layer 36. An opening 37a is formed in the resist pattern 37 in a portion of the chip portion 101. The seed layer 36 is exposed at the bottom surface of the opening 37a. The resist pattern 37 covers the chip ring portion 102 and the dicing portion 103.

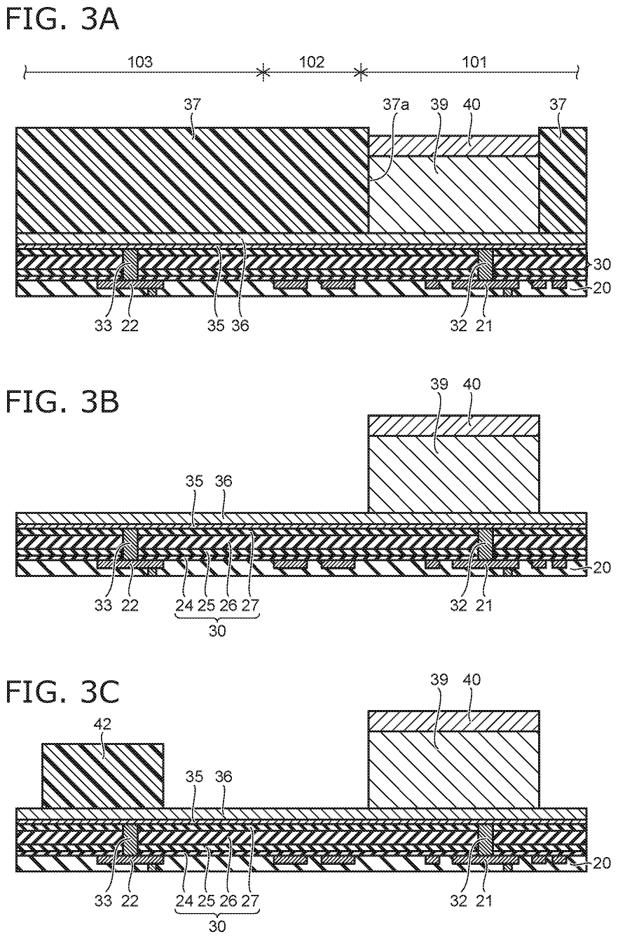

Continuing as shown in FIG. 3A, copper is electroplated on the portion of the seed layer 36 exposed inside the opening 37a of the resist pattern 37 by applying a potential to the seed layer 36. Thereby, a metal plate 39 that is made of copper is formed inside the opening 37a. The metal plate 39 is formed to be thicker than the seed layer 36. The thickness of the metal plate 39 is, for example, about 10 μm. Then, a conductive capping layer 40 is formed on the upper surface of the metal plate 39. The capping layer 40 includes, for example, nickel (Ni), palladium (Pd), or gold (Au).

Then, the resist pattern 37 is removed as shown in FIG. 3B. Thus, the metal plate 39 and the capping layer 40 are formed only in the chip portion 101.

Continuing, a resist pattern 42 is formed as shown in FIG. 3C. The resist pattern 42 covers a portion of the portion of the seed layer 36 formed in the dicing portion 103.

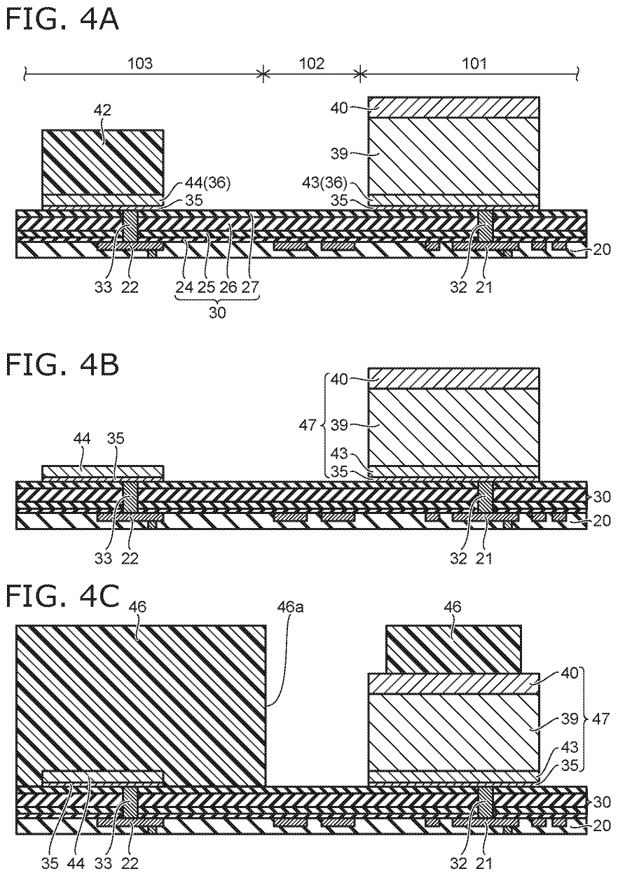

Then, as shown in FIG. 4A, the etching such as RIE or the like of the seed layer 36 and the barrier metal layer 35 is performed using the capping layer 40, the metal plate 39, and the resist pattern 42 as a mask. The seed layer 36 and the barrier metal layer 35 are selectively removed thereby. As a result, a seed layer 43 remains in the region directly under the metal plate 39; and a seed layer 44 remains in the region directly under the resist pattern 42.

Continuing, the resist pattern 42 is removed as shown in FIG. 4B. Thus, a stacked body 47 that is made of the barrier metal layer 35, the seed layer 43, the metal plate 39, and the capping layer 40 is formed on the insulating film 30 in the chip portion 101. The stacked body 47 is not formed in the chip ring portion 102 and the dicing portion 103.

Then, a resist pattern 46 is formed as shown in FIG. 4C. An opening 46a is formed in the resist pattern 46 in the region directly above the peripheral portion of the stacked body 47. The resist pattern 46 covers the central portion of the stacked body 47 and the entire seed layer 44.

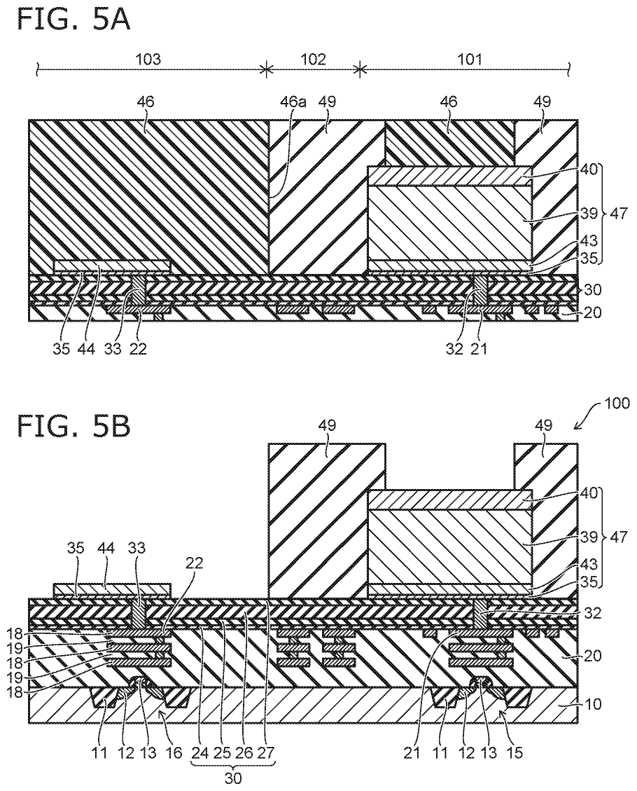

Continuing as shown in FIG. 5A, a protective film 49 that covers the peripheral portion of the stacked body 47 is formed by filling an insulating material, e.g., silicon oxide inside the opening 46a of the resist pattern 46. Then, the resist pattern 46 is removed.

Thereby, a circuit wafer 100 is made as shown in FIG. 5B and FIG. 6. The chip portion 101 and the dicing portion 103 surrounding the chip portion 101 are set in the circuit wafer 100. The configuration of the chip portion 101 is, for example, a rectangle; and the configuration of the dicing portion 103 is, for example, a lattice configuration. The chip ring portion 102 is not illustrated in FIG. 6. The chip ring portion 102 is disposed between the chip portion 101 and the dicing portion 103 and has, for example, a frame-like configuration. The components of the chip portion 101 are illustrated fewer and larger than the actual components in FIG. 6.

The semiconductor wafer 10 is provided in the circuit wafer 100; and the multilayer interconnect layer 20 is provided on the semiconductor wafer 10. The element 15 is provided in the chip portion 101 inside the semiconductor wafer 10 and the multilayer interconnect layer 20. The element 16 is provided in the dicing portion 103 inside the semiconductor wafer 10 and the multilayer interconnect layer 20. The interconnect 21 is provided in the uppermost layer of the multilayer interconnect layer 20 in the chip portion 101. The interconnect 21 is connected to the element 15. The interconnect 22 is provided in the uppermost layer of the multilayer interconnect layer 20 in the dicing portion 103. The interconnect 22 is connected to the element 16.

The insulating film 30 is provided on the multilayer interconnect layer 20. The silicon nitride layer 24, the silicon oxide layer 25, the silicon nitride layer 26, and the silicon oxide layer 27 are stacked in this order in the insulating film 30. The insulating film 30 covers the interconnects 21 and 22. The plug 32 that is made of, for example, tungsten is provided inside the insulating film 30 in the chip portion 101. The plug 33 that is made of, for example, tungsten is provided inside the insulating film 30 in the dicing portion 103.

The stacked body 47 is provided on the insulating film 30 in the chip portion 101. In the stacked body 47, for example, the barrier metal layer 35 that includes titanium, the seed layer 43 that includes copper, the metal plate 39 that includes copper, and the capping layer 40 that includes, for example, nickel, palladium, or gold are stacked in this order. The metal plate 39 is thicker than the seed layer 43. The capping layer 40 is connected to the element 15 via the metal plate 39, the seed layer 43, the barrier metal layer 35, the plug 32, and the interconnect 21. The protective film 49 that is made of an insulating material is provided around the stacked body 47.

For example, the barrier metal layer 35 that includes titanium and the seed layer 44 that includes copper are provided on the insulating film 30 in the dicing portion 103. The thickness of the seed layer 44 is substantially the same as the thickness of the seed layer 43. The seed layer 44 is connected to the element 16 via the barrier metal layer 35, the plug 33, and the interconnect 22.

Then, as shown in FIG. 7A, the electrical characteristics of the element 16 are evaluated via the seed layer 44 provided in the dicing portion 103 by causing a probe P to contact the seed layer 44. The final quality of the circuit wafer 100 is evaluated thereby.

Continuing as shown in FIG. 7B, the dicing portion 103 is removed by cutting by a blade (not illustrated). At this time, the element 16, the seed layer 44, etc., also are removed by the cutting. Thereby, the chip portion 101 is singulated by dicing the circuit wafer 100. Thus, the semiconductor device 1 is manufactured. For the semiconductor device 1, one chip portion 101 is provided; and the chip ring portion 102 is provided around the chip portion 101. The semiconductor device 1 is, for example, a power device for power control.

Effects of the embodiment will now be described.

In the embodiment as shown in FIG. 7B, the thick metal plate 39 is provided on the upper surface of the semiconductor device 1. As described above, the metal plate 39 is connected to the internal circuit of the semiconductor device 1, i.e., the circuit including the element 15. The ON-resistance of the semiconductor device 1 can be reduced thereby.

The seed layer 44 that includes copper is provided on the upper surface of the dicing portion 103 in the circuit wafer 100. Thereby, the electrical characteristics of the element 16 can be evaluated by causing the probe P to contact the seed layer 44 in the process shown in FIG. 7A. Therefore, the evaluation of the element 16 is easy.

Because the seed layer 44 is thinner than the metal plate 39, it is unnecessary to cut the thick metal plate 39 when dicing the circuit wafer 100 in the process shown in FIG. 7B. Clogging of the blade and chipping of the semiconductor device 1 can be suppressed thereby. As a result, in the embodiment, the productivity of the semiconductor device 1 is high.

### Second Embodiment

A method for manufacturing a semiconductor device according to a second embodiment will now be described.

The configuration of connecting the metal plate 39 and the seed layer 44 to the interconnects 21 and 22 in the embodiment is different from that of the first embodiment described above.

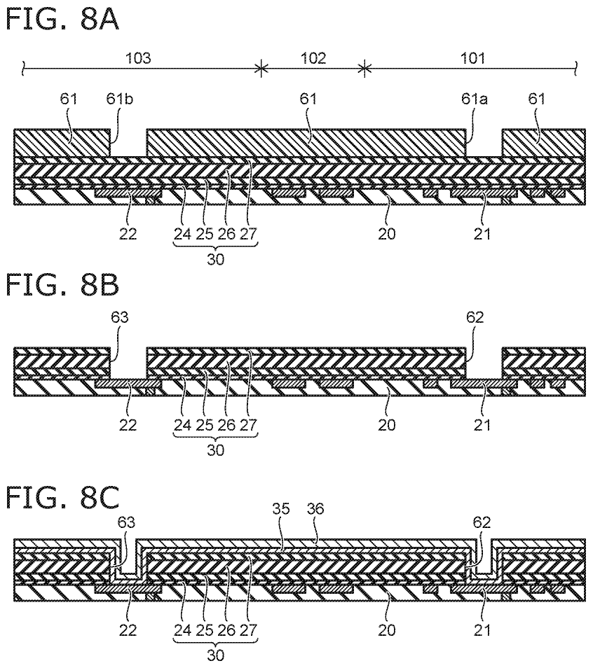

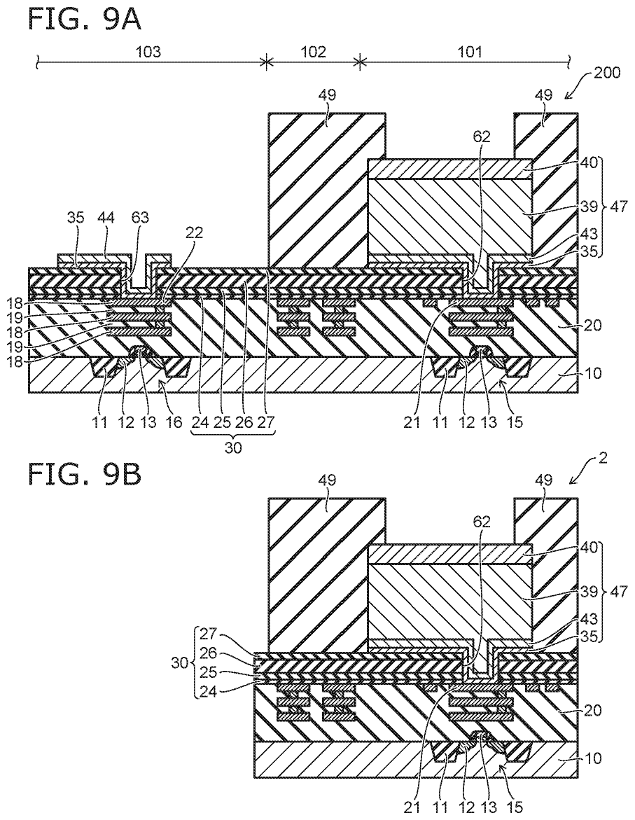

FIGS. 8A to 8C and FIGS. 9A and 9B are cross-sectional views showing the method for manufacturing the semiconductor device according to the embodiment.

The semiconductor wafer 10 and the lower portion of the multilayer interconnect layer 20 are not illustrated in FIGS. 8A to 8C.

First, the processes shown in FIGS. 1A and 1B are performed.

Then, as shown in FIG. 8A, a resist pattern 61 is formed on the insulating film 30. Openings 61a and 61b are formed in the resist pattern 61. The opening 61a is formed in a portion of the region directly above the interconnect 21; and the opening 61b is formed in a portion of the region directly above the interconnect 22.

Continuing as shown in FIG. 8B, the etching such as RIE or the like of the insulating film 30 is performed using the resist pattern 61 as a mask. Thereby, a through-hole 62 that reaches the interconnect 21 is formed in the insulating film 30 in the region directly under the opening 61a; and a through-hole 63 that reaches the interconnect 22 is formed in the insulating film 30 in the region directly under the opening 61b. Then, the resist pattern 61 is removed.

Then, as shown in FIG. 8C, the barrier metal layer 35 and the seed layer 36 are formed by a method similar to the first embodiment. At this time, the barrier metal layer 35 and the seed layer 36 are formed also on the inner surface of the through-hole 62 and on the inner surface of the through-hole 63 in addition to the upper surface of the insulating film 30. Thereby, the barrier metal layer 35 contacts the interconnects 21 and 22.

Continuing, the processes shown in FIG. 2C to FIG. 5B are performed. At this time, a portion of the metal plate 39 is formed inside the through-hole 62.

Thus, a circuit wafer 200 according to the embodiment is made as shown in FIG. 9A. In the circuit wafer 200, the barrier metal layer 35 and the seed layer 43 also are formed on the inner surface of the through-hole 62 in the chip portion 101. The barrier metal layer 35 contacts the interconnect 21 at the bottom surface of the through-hole 62. A portion of the metal plate 39 is disposed inside the through-hole 62. Similarly, the barrier metal layer 35 and the seed layer 44 are formed also on the inner surface of the through-hole 63 in the dicing portion 103. The barrier metal layer 35 contacts the interconnect 22 at the bottom surface of the through-hole 63.

Then, the process shown in FIG. 7A is performed. Thereby, the electrical characteristics of the element 16 are evaluated via the seed layer 44.

Continuing as shown in FIG. 9B, the chip portion 101 is singulated by removing the dicing portion 103 of the circuit wafer 200. Thus, the semiconductor device 2 according to the embodiment is manufactured.

Effects of the embodiment will now be described.

In the semiconductor device 2 according to the embodiment, a portion of the metal plate 39 is disposed inside the through-hole 62 of the insulating film 30. As a result, the anchor effect can suppress undesirable movement of the metal plate 39 on the insulating film 30 when stress such as thermal stress or the like is applied.

Otherwise, the manufacturing method, the configuration, and the effects of the embodiment are similar to those of the first embodiment.

According to the embodiments described above, a circuit wafer and a method for manufacturing a semiconductor device can be realized in which the productivity is high.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, comprising:
forming a first interconnect on a first portion disposed in a chip portion of a semiconductor wafer and forming a second interconnect on a second portion disposed in a dicing portion of the semiconductor wafer;
forming an insulating film covering the first interconnect and the second interconnect;
forming a seed layer on the insulating film, the seed layer being connected to the first interconnect and the second interconnect;
forming a metal plate on a portion of the seed layer disposed in the chip portion, the metal plate being thicker than the seed layer; and
singulating the chip portion by removing the dicing portion.

2. The method according to claim 1, wherein the seed layer and the metal plate include copper.

3. The method according to claim 1, further comprising:
forming a first element in the first portion and forming a second element in the second portion, the first element being connected to the first interconnect, the second element being connected to the second interconnect; and
evaluating an electrical characteristic of the second element via the seed layer.

4. The method according to claim 1, further comprising:
forming a first resist pattern on the insulating film, the first resist pattern having a first opening and a second opening, the first opening being formed in a portion on the first interconnect, the second opening being formed in a portion on the second interconnect;
forming a first through-hole and a second through-hole in the insulating film by etching the insulating film using the first resist pattern as a mask, the first through-hole reaching the first interconnect, the second through-hole reaching the second interconnect;
removing the first resist pattern; and
forming a first plug inside the first through-hole and forming a second plug inside the second through-hole,
in the forming of the seed layer, the seed layer being connected to the first plug and the second plug.

5. The method according to claim 1, further comprising:
forming a first resist pattern on the insulating film, the first resist pattern having a first opening and a second opening, the first opening being formed in a portion on the first interconnect, the second opening being formed in a portion on the second interconnect;
forming a first through-hole and a second through-hole in the insulating film by etching the insulating film using the first resist pattern as a mask, the first through-hole reaching the first interconnect, the second through-hole reaching the second interconnect; and
removing the first resist pattern,
in the forming of the seed layer, the seed layer being formed also on an inner surface of the first through-hole and on an inner surface of the second through-hole,
in the forming of the metal plate, the metal plate being formed also inside the first through-hole.

6. The method according to claim 1, wherein
the forming of the metal plate includes:
forming a second resist pattern having an opening formed in the chip portion;
electroplating a metal on a portion of the seed layer exposed inside the opening; and
removing the second resist pattern.

7. The method according to claim 1, further comprising:
forming a third resist pattern covering a portion of the seed layer formed in the dicing portion;
causing a first seed layer to remain in a region directly under the metal plate and causing a second seed layer to remain in a region directly under the third resist pattern by etching the seed layer using the metal plate and the third resist pattern as a mask; and
removing the third resist pattern.

8. The method according to claim 7, further comprising:
forming a fourth resist pattern, an opening being formed in the fourth resist pattern to leave a peripheral portion of the metal plate exposed;
forming a protective film inside the opening of the fourth resist pattern; and
removing the fourth resist pattern.

9. A circuit wafer, comprising:
a semiconductor wafer;
a first interconnect provided on the semiconductor wafer in a chip portion;
a second interconnect provided on the semiconductor wafer in a dicing portion;
an insulating film covering the first interconnect and the second interconnect;
a first seed layer connected to the first interconnect and provided on the insulating film in the chip portion;
a second seed layer connected to the second interconnect and provided on the insulating film in the dicing portion; and
a metal plate provided on the first seed layer, the metal plate being thicker than the first seed layer.

10. The circuit wafer according to claim 9, wherein the first seed layer, the second seed layer, and the metal plate include copper.

11. The circuit wafer according to claim 9, further comprising:
a first element provided in the chip portion and connected to the first interconnect; and
a second element provided in the dicing portion and connected to the second interconnect.

12. The circuit wafer according to claim 9, further comprising:
a first plug connecting the first seed layer to the first interconnect and being provided inside the insulating film; and
a second plug connecting the second seed layer to the second interconnect and being provided inside the insulating film.

13. The circuit wafer according to claim 9, wherein
a first through-hole and a second through-hole are formed in the insulating film;
a portion of the first seed layer and a portion of the metal plate are disposed inside the first through-hole; and
a portion of the second seed layer is disposed inside the second through-hole.
